(19) United States
(12) Patent Application Publication
(10) Pub. No.: US 2023/0327026 A1
(43) Pub. Date: Oct. 12, 2023

(54) POWER SEMICONDUCTOR DEVICE WITH SHALLOW CONDUCTION REGION

(71) Applicant: Wolfspeed, Inc., Durham, NC (US)

(72) Inventors: Rahul R. Potera, Apex, NC (US); Thomas E. Harrington, III, Durham, NC (US); Edward Robert Van Brunt, Cary, NC (US); Madankumar Sampath, Morrisville, NC (US)

(21) Appl. No.: 17/705,172

(22) Filed: Mar. 25, 2022

(51) Int. Cl. H01L 29/808; H01L 29/16; H01L 29/66

(52) U.S. Cl. CPC H01L 29/8083; H01L 29/1608; H01L 29/66068; H01L 29/66909

(57) ABSTRACT

A power transistor device includes a drift layer having a first conductivity type and a mesa on the drift layer. The mesa includes a channel region on the drift layer, a source layer on the channel region and a gate region in the mesa adjacent the channel region. The channel region and the source layer have the first conductivity type, and the gate region has a second conductivity type opposite the first conductivity type. The channel region includes a deep conduction region and a shallow conduction region between the deep conduction region and the gate region. The deep conduction region has a first doping concentration, and the shallow conduction region has a second doping concentration that is greater than the first doping concentration.

### FIELD

The present disclosure relates to semiconductor devices. In particular, the disclosure relates to junction field effect transistor (JFET) power semiconductor devices.

### BACKGROUND

A conventional n-channel vertical JFET structure 10 is shown in FIG. 1A. The vertical JFET structure 10 includes an n+ drain layer 26 on which an n- drift layer 15 is formed. An n-type channel region 24 is on the drift layer 15, and an n+ source layer 16 is on the channel region 14. An n++ source contact layer 38 is on the n+ source layer. A drain ohmic contact 28 is on the drain layer 26, and a source ohmic contact 40 is on the source contact layer 38. The channel region 24, source layer 16 and source contact layer 38 are provided as part of a mesa 12 above the drift layer 15. A p+ gate region 18 is provided as part of the mesa 12 adjacent the channel region 24. A p++ shield region 32 is provided adjacent the gate region 18, and a gate ohmic contact 36 is formed on the shield region 32. A passivation layer 42 is on the gate ohmic contact 36 and the shield region 32.

FIG. 1A illustrates one half of a vertical JFET unit cell structure 10. The entire structure is symmetrical about the axis 30 and includes two gate regions 18 as part of the mesa 12 on opposite sides of the channel region 24. That is, only a half-cross section of a JFET device is shown in FIG. 1A. The depicted portion can be mirrored around the vertical axis 30 to obtain the full pitch of a unit cell of the device. The full JFET device includes many such unit cells. For clarity, FIG. 1C illustrates an entire JFET unit cell 10 including half-cells 10A, 10B that share the same mesa 12.

Referring again to FIG. 1A, the channel of the vertical JFET structure 10 is formed within the mesa 12. The channel breadth in the n-type region is in the horizontal direction away from the p-n junction between the gate region 18 and the channel region 24. The channel width is into the plane of FIG. 1A, and the channel length is in the vertical direction. Such a vertical JFET structure with a short channel length may also be called a static-induction transistor (SIT). In a SIT, the channel length is chosen based on a trade-off between low on-resistance in the on-state (short channel) and resistance to drain-induced barrier lowering (DIBL) in the off-state. A conventional p-channel JFET may have a similar structure, but the conductivity types are reversed from those shown in FIG. 1A.

In operation, conductivity between the source layer 16 and the drain layer 26 is modulated by applying a reverse bias to the gate region 18 relative to the source layer 16. To switch off an n-channel device such as the JFET structure 10, a negative gate-to-source voltage, or simply gate voltage (V_{GS}) is applied to the gate region 18. When no voltage is applied to the gate region 18, charge carriers can flow freely from the source layer 16 through the channel region 24 and the drift layer 15 to the drain layer 26. Conversely, referring to FIG. 1B, when a reverse bias is applied to the gate region 18, a depletion region 33 is formed at the interface between the gate region 18 and the surrounding n-type regions, namely, the channel region 24, and the source layer 16. The depletion region 33 may extend into the drift layer 15. As its name suggests, the depletion region 33 is depleted of charge carriers. When the magnitude of the reverse bias applied to the gate region 18 is large enough, the depletion region extends to cover the entire breadth of the channel region 24, pinching off the channel region 24 and impeding or blocking the flow of charge carriers between the source layer 16 and the drift layer 15. As indicated in FIG. 1A, in a mesa JFET structure 10, the “breadth” of the channel region 24 is in the same direction as the width of the mesa 12. Thus, the lateral width of the mesa 12 defines the breadth of the channel region 24.

The threshold voltage of a JFET device refers to the gate voltage at which the device begins to conduct. Because pinch-off of the channel region 24 occurs when the gate voltage is large enough for the depletion region 33 to span the entire channel layer 24, the threshold voltage of the device is very sensitive to the breadth of the channel region 24. As noted, in the conventional vertical JFET structure 10 shown in FIGS. 1A and 1B, the breadth of the channel region 24 is determined by the width of the mesa 12. The width of the mesa 12 is determined by the manufacturing processes used to form the mesa 12, namely, masking and etching processes. Such manufacturing processes are subject to various tolerances. Manufacturing variations within these tolerances can lead to significant variations in threshold voltage from device to device, even within the same manufacturing run.

### SUMMARY

A power transistor device according to some embodiments includes a drift layer having a first conductivity type and a mesa on the drift layer. The mesa includes a channel region on the drift layer, a source layer on the channel region and a gate region in the mesa adjacent the channel region. The channel region and the source layer have the first conductivity type, and the gate region has a second conductivity type opposite the first conductivity type. The channel region includes a deep conduction region and a shallow conduction region between the deep conduction region and the gate region. The deep conduction region has a first doping concentration, and the shallow conduction region has a second doping concentration that is greater than the first doping concentration.

In some embodiments, the shallow conduction region extends vertically between the drift layer and the source layer, and wherein the deep conduction region extends vertically between the drift layer and the source layer.

The channel region may include silicon carbide, and the shallow conduction region may have a doping concentration greater than about 1E17 cm⁻³ and the deep conduction region may have a doping concentration less than about 1E17 cm⁻³.

The channel region may include silicon carbide, and the shallow conduction region may have a doping concentration of about 3E17 cm⁻³ to about 5E18 cm⁻³. The deep conduction region may have a doping concentration of about 1E16 cm⁻³ to about 5E16 cm⁻³. In some embodiments, the shallow conduction region may have a doping concentration of about 1E18 cm⁻³ and the deep conduction region may have a doping concentration of about 1.5E16 cm⁻³. The shallow conduction region may have a doping concentration at least about 10 times greater than a doping concentration of the deep conduction region.

The shallow conduction region may have a graded doping profile that is graded in a lateral direction that is perpendicular to a direction of carrier flow through the channel region when the vertical junction field effect device is in an on-state.

The shallow conduction region may have a breadth of about 0.1 to 0.3 microns in a lateral direction that is perpendicular to a direction of carrier flow through the channel region when the vertical junction field effect device is in an on-state.

The shallow conduction region may have a breadth in a lateral direction that is perpendicular to a direction of carrier flow through the channel region when the vertical junction field effect device is in an on-state that may be about one third of a half-width of the mesa. The shallow conduction region may include an implanted region within the mesa.

The power transistor device may further include a breakdown adjustment region between the shallow conduction region and the gate region. The breakdown adjustment region may have the first conductivity type and may have a third doping concentration less than the second doping concentration of the shallow conduction region.

The vertical junction field effect device exhibits a change in threshold voltage as a function of mesa width of less than 20 V/micron, in some embodiments less than 10 V/micron, and in some embodiments less than 5 V/micron.

The power transistor device may be a junction field effect transistor (JFET). The drift layer, the channel region and the gate region may include silicon carbide.

A breadth of the shallow channel region in a lateral direction that may be perpendicular to a direction of current flow when the device may be in an on-state may be independent of a width of the mesa in the lateral direction.

A breadth of the deep channel region in a lateral direction that is perpendicular to a direction of current flow when the device is in an on-state may be directly proportional to a width of the mesa in the lateral direction.

The gate region may include a first gate region and the shallow conduction region may include a first shallow conduction region, and the power transistor device may further include a second gate region in the mesa opposite the first gate region, where the channel region is between the first gate region and the second gate region. The device may include a second shallow conduction region in the channel region between the deep conduction region and the second gate region. The second shallow conduction region may have a third doping concentration that is greater than the first doping concentration of the deep conduction region.

The first gate region may be surrounded by a breakdown adjustment region in the mesa, such that the breakdown region is above, below and on a side of the gate region adjacent the channel region in the mesa. The breakdown adjustment region may have the first conductivity type and a third doping concentration that may be less than the second doping concentration of the shallow conducting region.

The deep conduction region and the channel region may be arranged on opposite sides of the shallow conduction region in a lateral direction that is perpendicular to a direction of current flow in the power transistor device

A power transistor device according to some embodiments includes a drift layer having a first conductivity type, a mesa on the drift layer, the mesa including a channel region on the drift layer and a source layer on the channel region, and a gate region in the mesa on a side of the channel region. The channel region and the source layer have the first conductivity type. The gate region has a second conductivity type opposite the first conductivity type. The vertical junction field effect device exhibits a change in threshold voltage as a function of mesa width of less than 20 V/micron.

A method of forming a power transistor device includes providing a drift layer having a first conductivity type, forming a source layer having the first conductivity type on the drift layer, forming a mesa by selectively etching a portion of the source layer and the drift layer to form a trench that extends into the drift layer and defines the mesa adjacent the trench, the mesa having a mesa sidewall adjacent the trench, forming a shallow conduction region in the mesa that extends between the drift layer and the source layer, and forming a gate region having a second conductivity type in the mesa, wherein the gate region may be adjacent a channel region in the mesa. The channel region includes a deep conduction region adjacent the shallow conduction region and the shallow conduction region may be between the deep conduction region and the gate region, and the shallow conduction region may have a higher doping concentration than the deep conduction region.

Forming the shallow conduction region may include performing an angled ion implantation of first conductivity type dopant ions into the mesa sidewall at a first implant energy to form the shallow conduction region in the mesa, wherein a portion of the drift layer in the mesa forms the deep conduction region adjacent the shallow conduction region.

Forming the gate region may include implanting second conductivity type dopant ions into the mesa sidewall at a second implant energy that may be lower than the first implant energy to form the gate region in the mesa, wherein the shallow conduction region may be between the gate region and the deep conduction region, and wherein the second conductivity type is opposite the first conductivity type.

Forming the mesa may include forming an etch mask on the source layer, and etching the source layer and the drift layer to form the mesa in a region below the etch mask. Forming the shallow conduction region may include implanting the first conductivity type dopant ions into the mesa sidewall using the etch mask as an implant mask.

The etch mask may include an SiO₂ etch mask on the source layer and a silicon nitride mask on the SiO₂ mask, and the method may further include forming a second etch mask on the mesa and the trench, patterning the second etch mask to expose the mesa and a floor of the trench adjacent the mesa and to expose one or more surface regions in an edge region of the device, and implanting second conductivity type dopant ions into the mesa sidewall and the junction termination regions at a second implant energy that is lower than the first implant energy to form the gate region in the mesa and to form edge termination regions in the edge region. The shallow conduction region is between the gate region and the deep conduction region, and the second conductivity type is opposite the first conductivity type.

The second etch mask may include SiO₂, and patterning the second etch mask may include selectively etching the second etch mask using the silicon nitride mask as an etch stop layer.

A power transistor device according to some embodiments includes a drift layer having a first conductivity type, a mesa on the drift layer, the mesa including a channel region on the drift layer and a source layer on the channel region, the channel region and the source layer having the first conductivity type, and a gate region in the mesa adjacent the channel region, the gate region having a second conductivity type opposite the first conductivity type. A breakdown adjustment region may be provided in the mesa between the channel region and the gate region, the breakdown adjustment region having the first conductivity type. The channel region may have a first doping concentration and wherein the breakdown adjustment region may have a second doping concentration that may be less than the first doping concentration.

The channel region may include a deep conduction region and a shallow conduction region between the deep conduction region and the breakdown adjustment region. The shallow conduction region may have the first doping concentration and the deep conduction region may have a third doping concentration that may be less than the first doping concentration. The breakdown adjustment region surrounds the gate region in the mesa.

### BRIEF DESCRIPTION OF THE DRAWINGS

The accompanying drawings, which are included to provide a further understanding of the disclosure, are incorporated in and constitute a part of this specification, illustrate aspects of the disclosure and together with the detailed description serve to explain the principles of the disclosure. No attempt is made to show structural details of the disclosure in more detail than may be necessary for a fundamental understanding of the disclosure and the various ways in which it may be practiced. In the drawings:

FIGS. 1A, 1B, and 1C illustrate conventional JFET device structures.

FIGS. 2A and 2B illustrate JFET device structures according to some embodiments.

FIG. 2C illustrates channel doping profiles for JFET device structures according to some embodiments.

FIG. 3 illustrates a channel doping profile and associated electric field strength and electron energy for a JFET device structure according to some embodiments.

FIGS. 4A to 4I illustrate operations for fabricating a JFET device structure according to some embodiments.

FIG. 5A illustrates operations for fabricating a JFET device structure according to further embodiments.

FIG. 5B illustrates a JFET device structure according to further embodiments.

FIGS. 5C, 5D and 5E illustrate some possible channel doping profiles for the JFET device structure of FIG. 5B.

FIG. 6 illustrates an example circuit that includes a JFET device according to some embodiments.

FIG. 7 is a flowchart illustrating operations for fabricating a JFET device according to some embodiments.

### DETAILED DESCRIPTION OF THE DISCLOSURE

Embodiments of the inventive concepts are explained more fully with reference to the non-limiting aspects and examples that are described and/or illustrated in the accompanying drawings and detailed in the following description. It should be noted that the features illustrated in the drawings are not necessarily drawn to scale, and features of some embodiments may be employed with other aspects as the skilled artisan would recognize, even if not explicitly stated herein. Descriptions of well-known components and processing techniques may be omitted so as to not unnecessarily obscure the aspects of the disclosure. The examples used herein are intended merely to facilitate an understanding of ways in which the disclosure may be practiced and to further enable those of skill in the art to practice the aspects of the disclosure. Accordingly, the examples and aspects herein should not be construed as limiting the scope of the disclosure, which is defined solely by the appended claims and applicable law. Moreover, it is noted that like reference numerals represent similar parts throughout the several views of the drawings.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the another element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the another element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular aspects only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art.

Although a JFET device is sometimes referred to as a static induction transistor, the term JFET will be used in the description below. However, it will be appreciated that embodiments described herein may be applied to any device that uses a depletion region to modulate the conductivity of a channel in a mesa.

Power electronic devices manufactured using silicon carbide (SiC) are capable of high blocking voltages. For power devices having blocking voltages in the 600 V-1000 V range, SiC JFETs have two to three times smaller chip area than SiC MOSFETs. SiC JFETs can also be manufactured with a simpler manufacturing process than MOSFETs, which can lead to lower manufacturing costs. Moreover, SiC JFET devices have no SiO₂-SiC interface. This may increase device reliability, as oxide layers may break down under high voltage operation. JFET devices have the drawback of being normally-on devices. However, their advantages may outweigh their disadvantages in power applications, such as high reliability Si-SiC heterogeneously integrated circuits.

In a vertical SiC JFET device that is optimized for low resistance, it is desirable for the device to have a predictable threshold voltage for circuit performance. However, as noted above, the threshold voltage of a vertical JFET is highly sensitive to the width of the mesa of the device. Some embodiments described herein are based on a realization that the sensitivity of threshold voltage to mesa width in a vertical JFET device is a function of the conductivity of the part of the channel that varies in breadth with mesa width. Some embodiments described herein may reduce the sensitivity of the threshold voltage to mesa width variation by providing a stepped or graded doping profile in the channel region.

For example, in some embodiments, the channel is divided into a highly conductive shallow channel region near the gate region and a less conductive deep channel region. In some embodiments, the shallow channel maybe self-aligned to the mesa edge, so that only the breadth of the less conductive deep channel region is sensitive to mesa width. This may reduce the sensitivity of the threshold voltage of the device to the mesa width. The total median conductivity of the channel itself may be kept constant or nearly constant, since the conductivity of the channel is dominated by the highly conductive shallow channel region. Some embodiments may provide a reduction in sensitivity of threshold voltage to mesa width by over an order of magnitude with appropriate choices of doping concentrations of the shallow and deep channel regions.

Accordingly, some embodiments may avoid the conventional trade-off between conductivity of a JFET channel and the sensitivity of threshold voltage to mesa width variation. That is, in a conventional structure, the more conductive the channel is made, the more sensitive it is to mesa width variations. Accordingly, some embodiments may allow mesa width to be narrowed and also allow the channel region to be more highly doped to increase conductivity, while reducing the sensitivity of threshold voltage to mesa width.

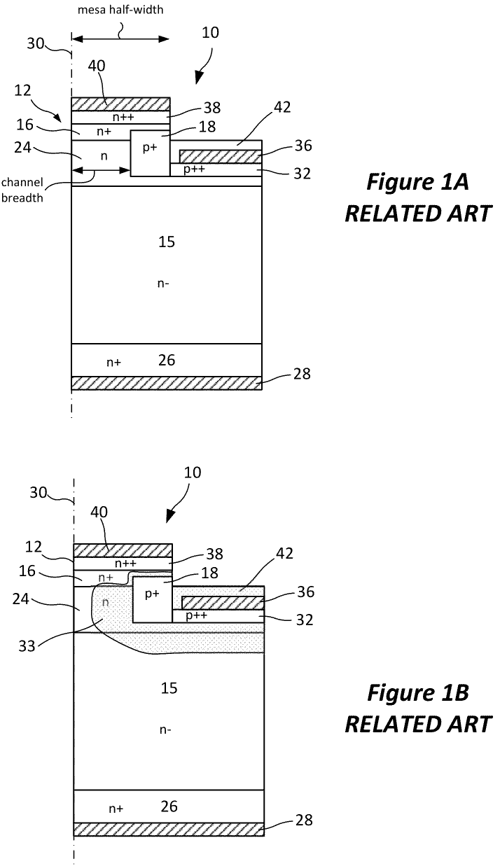

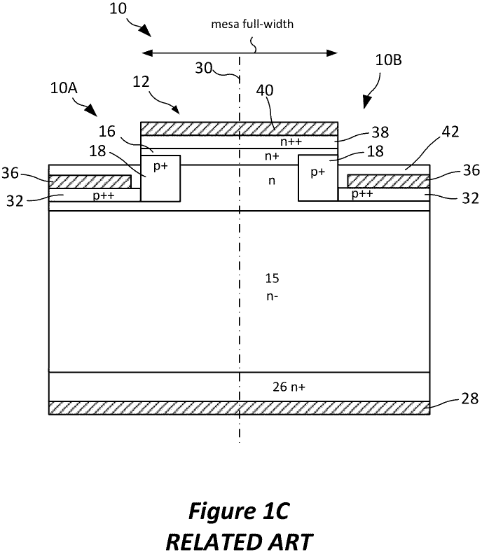

As illustrated in FIGS. 1A and 1B, the JFET channel of a conventional structure has a substantially constant doping so as to have uniform conductivity regardless of channel breadth. According to some embodiments described herein, the JFET channel doping is graded such that the deeper part of the JFET channel, which is near the center of the mesa, is more lightly doped, while the shallower part of the JFET channel (closer to the gate junction) is more heavily doped. Additionally, in some embodiments, the doping of the shallower part of the JFET channel may be self-aligned to the edge of the mesa. These aspects combine to desensitize the threshold voltage of the JFET device to variations in the width of the mesa while not suffering a trade-off in channel conductivity.

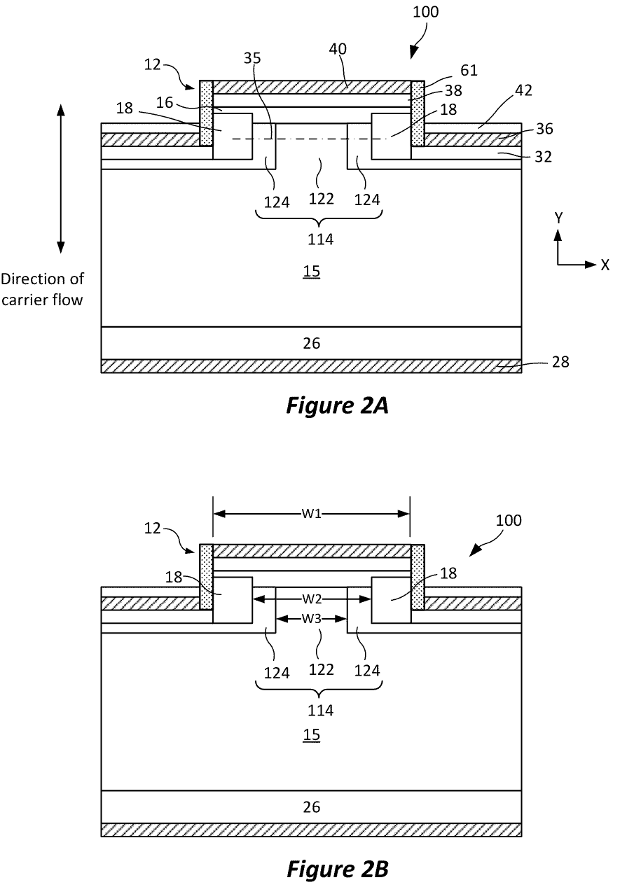

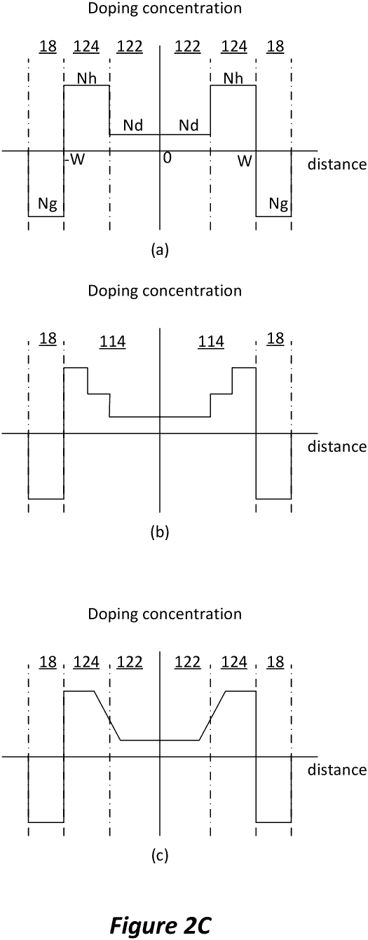

FIG. 2A illustrates an n-channel vertical JFET structure 100 according to some embodiments. The vertical JFET structure 100 includes an n+ drain layer 26 on which an n- drift layer 15 is formed. An n-type channel region 114 is on the drift layer 15, and an n+ source layer 16 is on the channel region 114. An n++ source contact layer 38 is on the n+ source layer. A drain ohmic contact 28 is on the drain layer 26, and a source ohmic contact 40 is on the source contact layer 38. The channel region 114, source layer 16 and source contact layer 38 are provided in a mesa 12 above the drift layer 15. A p+ gate region 18 is provided as part of the mesa 12 adjacent the channel region 24. A p++ shield region 32 is provided adjacent the gate region 18, and a gate ohmic contact 36 is formed on the shield region 32. A passivation layer 42 covers the gate ohmic contact 36 and the shield region 32. An optional sidewall protection layer 61 is on the exposed sidewall of the mesa 12. The sidewall protection layer 61 may have a thickness of, for example, 20 to 30 nm, in some embodiments 23 to 27 nm and in some embodiments 25 nm.

In some embodiments, the doping concentration of the channel region 114 may be graded along the width of the mesa 12 (corresponding to the breadth of the channel region 114) such that the channel region 114 has a lower doping concentration near the center of the mesa 12 and a higher doping concentration near the gate region 18.

For example, in the embodiments illustrated in FIG. 2A, the channel region 114 has a two-step grading profile, such that it is divided into a deep conduction region 122 and a shallow conduction region 124 that is between the deep conduction region 122 and the gate region 18. The channel region 114 includes both the shallow conduction region 124 and the deep conduction region 122 adjacent the gate region 18, and both the shallow conduction region 124 and the deep conduction region 122 may extend in the vertical direction between the drift layer 15 and the source layer 16. The shallow conduction region 124 extends vertically (e.g., in the y-direction, or in the direction of carrier flow, as shown in FIG. 2A) between the drift layer 15 and the source layer 16, and the deep conduction region 122 extends vertically between the drift layer 15 and the source layer 16. Thus, the deep conduction region 122 and the channel region 18 are arranged on opposite sides of the shallow conduction region 124 in a lateral direction (e.g., the x-direction) that is perpendicular to a direction of current flow in the device 100.

The deep conduction region 122 is provided near the center of the mesa 12, and has a doping concentration that is less than a doping concentration of the shallow conduction region 124. For example, the shallow conduction region 124 may have a doping concentration that is at least about 10 times greater than the doping concentration of the deep conduction region 122. In some cases, the shallow conduction region 124 may have a doping concentration that is at least about 20 times greater than the doping concentration of the deep conduction region 122, and in some cases at least about 100 times higher.

In some embodiments, the shallow conduction region 124 has a doping concentration of about 1E17 cm⁻³ or greater, such as between about 1E17 cm⁻³ and 1E19 cm⁻³. In some embodiments, the shallow conduction region 124 has a doping concentration of between about 3E17 cm⁻³ and 5E18 cm⁻³. In some embodiments, the shallow conduction region 124 has a doping concentration of about 1E18 cm⁻³.

In some embodiments, the deep conduction region 122 has a doping concentration of between about 5E15 cm⁻³ and 1E17 cm⁻³. In some embodiments, the deep conduction region 122 has a doping concentration of about 5E16 cm⁻³ or less, such as between about 5E15 cm⁻³ and 5E16 cm⁻³. In some embodiments, the deep conduction region 122 has a doping concentration of about 1.5E16 cm⁻³.

In some embodiments, the shallow conduction region has a doping concentration at least about 10 times greater than a doping concentration of the deep conduction region, and in some cases at least about 100 times greater.

The deep conduction region 122 may in some embodiments have the same doping concentration as the drift layer 15, since the shallow conduction region 124 may be formed via ion implantation into a portion of the epitaxial layer that forms the drift layer 15.

In some embodiments, the shallow conduction region 124 may have a breadth of about 0.1 to 0.3 microns in a lateral direction (the x-direction shown in FIG. 2A) that is perpendicular to a direction of carrier flow through the channel region 114 when the vertical JFET 100 is in an on-state (the y-direction shown in FIG. 2A). In some embodiments, the shallow conduction region has a breadth in a lateral direction that is perpendicular to a direction of carrier flow through the channel region when the vertical junction field effect device is in an on-state that is about one third of a half-width of the mesa.

Although illustrated as an n-channel device, it will be appreciated that the JFET device structure 100 could be formed as a p-channel device by switching the n-type layers to p-type, and vice versa.

In some embodiments, a vertical JFET 100 according to some embodiments may exhibit a change in threshold voltage as a function of mesa width of less than 20 V/micron. In some embodiments, a vertical JFET 100 according to some embodiments may exhibit a change in threshold voltage as a function of mesa width of less than 10 V/micron, and in some embodiments less than 5 V/micron.

Although a two-step graded doping profile is illustrated in FIG. 2A, the channel region 114 may have other doping profiles. For example, various possible doping profiles are shown in FIG. 2C, which includes graphs of various channel doping profiles across an entire mesa width according to some embodiments. In FIG. 2C, the total channel width is 2 W. Thus, each channel region 114 in one half of the mesa has a width of W.

FIG. 2C (a) illustrates a two-step doping profile in which each half of the mesa includes a more heavily doped shallow conduction region 124 and a more lightly doped deep conduction region 122. FIG. 2C (b) illustrates a three-step doping profile in the channel region 114. FIG. 2C (c) illustrates a doping profile in which the interface between the shallow conduction region 124 and the deep conduction region 122 is graded from a higher doping concentration to a lower doping concentration. The doping profiles illustrated in FIG. 2C are exemplary, and many other doping profiles are possible within the scope of the inventive concepts.

As shown in FIG. 2A, the shallow conduction region 124 extends vertically between the drift layer 15 and the source layer 16, and the deep conduction region 122 extends vertically between the drift layer 15 and the source layer 16.

In some embodiments, the shallow conduction region has a graded doping profile that is graded in a lateral direction that is perpendicular to a direction of carrier flow through the channel region when the vertical junction field effect device is in an on-state.

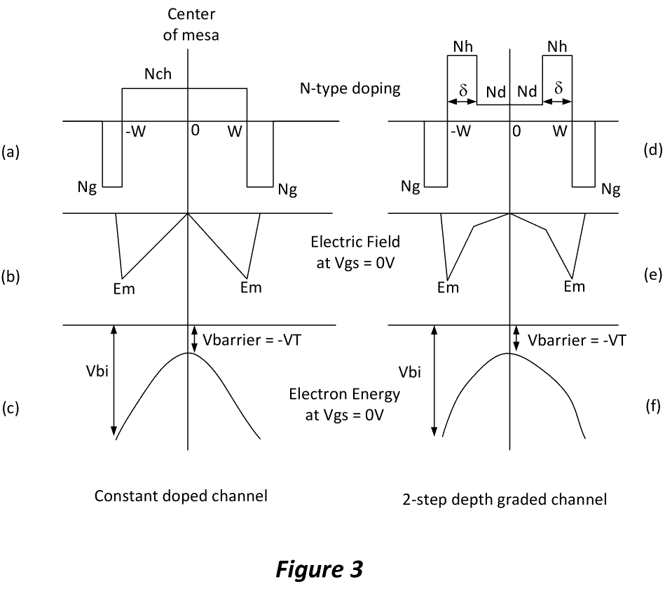

FIG. 3 (a) is a graph of doping concentration, FIG. 3 (b) is a graph of electric field strength, and FIG. 3 (c) is a graph of electron energy, as a function of position along the horizontal direction of the channel for a conventional JFET structure 10. Similarly, and FIG. 3 (d) is a graph of doping concentration, FIG. 3 (e) is a graph of electric field strength, and FIG. 3 (f) is a graph of electron energy as a function of position along the horizontal direction of the channel for a JFET structure 100 according to some embodiments.

As shown in FIG. 3 (a), in a conventional structure, the channel region has a constant doping concentration N_{ch}. In contrast, as shown in FIG. 3 (d), in a structure according to some embodiments, the channel region has a step-graded doping profile including a low doping concentration N_{d} in a deep conduction region away from the p-type gate region (which has a doping concentration N_{g} of the opposite type from that in the channel region) and a high doping concentration Nₕ in a shallow conduction region near the p-type gate region. The shallow conduction region may have a width δ of about 0.2 microns in some embodiments.

As shown in FIG. 3 (b) and 3 (e), the peak electric field (Eₘ) is higher in the JFET structure 100 because the junction is formed by a higher doped n-channel region than in the conventional structure 10, while the built-in voltage is same in both cases. The gate-source breakdown voltage is determined by the junction between the gate region 18 and the source layer 16, as long as Nh, the n+ doping of the shallower conduction region 124, is lower than the n+ doping concentration of the source layer 16. Accordingly, the JFET structure 100 should not have a lower gate-source breakdown voltage than the conventional JFET structure 10.

Solving the Poisson equation for electrostatics, the threshold voltage (V_{T}) and the sensitivity of V_{T} to mesa width for both the conventional constant doped structure and two-step breadth graded structure shown in FIG. 2A are obtained. In the embodiments described herein, sensitivity of V_{T} is lowered because N_{d} (the doping of the center of the channel) is lower than N_{ch} (the doping of the channel in the conventional structure).

For a constant doped channel with N_{ch}, V_{T} is calculated as:

$${V}_{T} = {V}_{b i} - \frac{q {N}_{c h} {W}^{2}}{2 ε} - {V}_{b a r r i e r}$$

The change in V_{T} as a function of mesa width W is calculated as:

$$\frac{d {V}_{T}}{d W} = - \frac{q {N}_{c h} W}{ε}$$

For a two-step doped channel with Nₕ and N_{d}, V_{T} is calculated as:

$${V}_{T} = {V}_{b i} - \left[\frac{q {N}_{d} {\left(W - δ\right)}^{2}}{2 ε} + \frac{q {N}_{d} \left(W - δ\right) δ}{2 ε} + \frac{q {N}_{h} {δ}^{2}}{2 ε}\right] - {V}_{b a r r i e r}$$

The change in V_{T} as a function of mesa width W is calculated as:

$$\frac{d {V}_{T}}{d W} = - \frac{q {N}_{d} W}{ε}$$

While V_{T} in the conventional structure is sensitive to N_{ch}, V_{T} in some embodiments is sensitive to the much lower value N_{d}.

A simulation was performed to compare the performance of a conventional structure with a structure according to some embodiments. The simulation used V_{T} as that gate voltage which would create a potential barrier in the channel to electron flow from the source (V_{barrier}) of 1.5V. The simulation used a mesa width of 1.2 microns, a mesa width variation of +/-0.2 microns, a p+ implant depth into the mesa of 0.2 microns on each side, an n+ implant depth into channel of 0.2 microns for the new structure, N_{ch} of 8E16 cm⁻³, N_{d} of 1E16 cm⁻³ and Nₕ of 3E17 cm⁻³. With these conditions, the analytical model above gives the results for V_{T} and variation of V_{T} shown in Table 1. As shown in Table 1, V_{T} of the conventional structure varied from -5.0 V to -16.6 V when the width of the mesa was varied by +/- 0.2 µm. In contrast, for a structure formed as described herein, V_{T} varied only from -9.3 V to -10.4 V when the width of the mesa was varied by +/- 0.2 microns.

Accordingly, variation of V_{T} with mesa width is shown to reduce by more than 10x when a structure as described herein is used.

TABLE 1

Variation of V_{T} with Mesa Width

| Design | Mesa (µm) | Channel (µm) | ΔMesa (µm) | Rch.sp (mΩcm2) | Rsp. (mΩcm2) | ΔRsp. (mΩcm2) | ΔRsp. (%) | V_{T} _{(V)} | VTmin (V) | VTmax (V) |
|---|---|---|---|---|---|---|---|---|---|---|
| Conventional | 1.2 | 0.8 | +/-0.2 | 0.2 | 0.8 | +/- 0.03 | +/-4 | -10.8 | -16.6 | -5.0 |
| New | 1.2 | 0.8 | +/-0.2 | 0.2 | 0.8 | <+/- 0.03 | +/-4 | -9.7 | -10.4 | -9.3 |

In some embodiments, a vertical junction field effect device may exhibit a change in threshold voltage as a function of mesa width of less than 20 V/micron. In some embodiments, the vertical junction field effect device exhibits a change in threshold voltage as a function of mesa width of less than 10 V/micron, and in some embodiments less than 5 V/micron. In some embodiments, the vertical junction field effect device exhibits a change in threshold voltage as a function of mesa width between 5 V/micron and 20 V/micron.

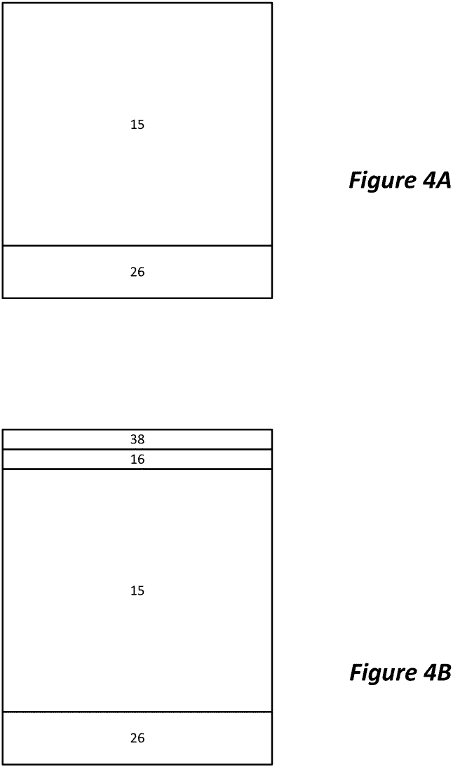

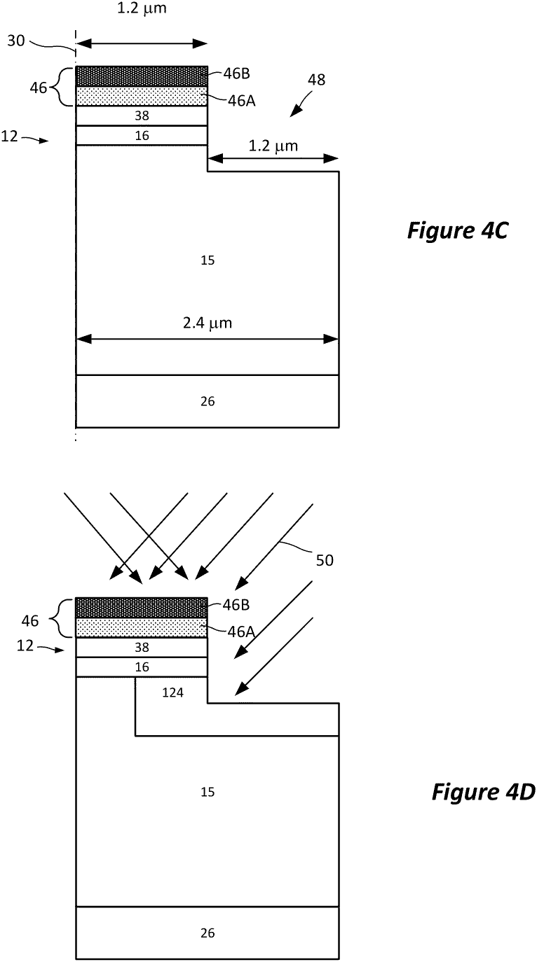

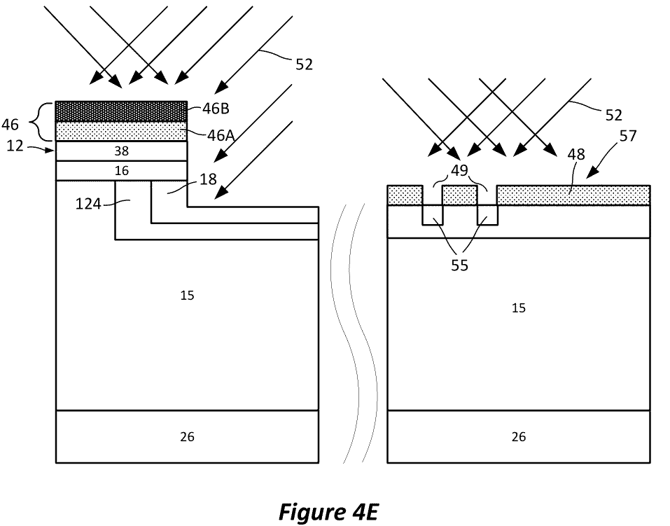

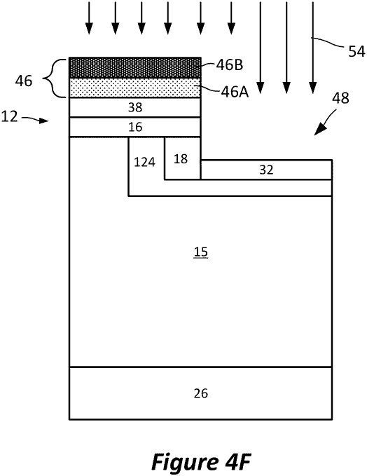

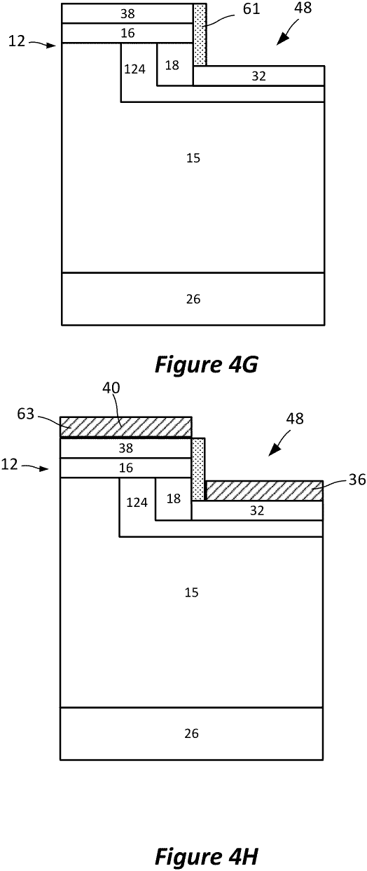

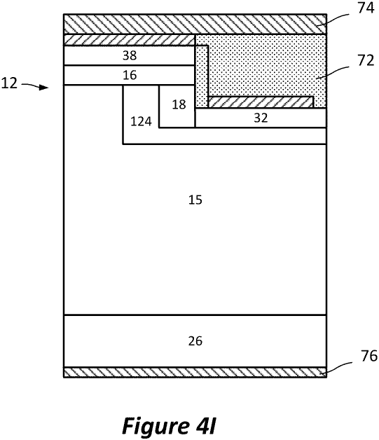

A process flow for forming a JFET structure according to some embodiments is illustrated in FIGS. 4A-4I. In FIGS. 4A-4I the relative sizes of various layers and regions are exaggerated for clarity and not drawn to scale. The process flow shown in FIGS. 4A-4I is for producing an n-channel JFET device. For a p-channel JFET device, the conductivity types of the layers/regions of the device would be reversed from n-type to p-type, and vice-versa.

Referring to FIG. 4A, an n+ SiC substrate 26 having a thickness of about 350 microns is provided. The substrate 26 may have a 2H, 4H, 6H or 3C polytype, and may have an on-axis or off-axis orientation. The n+ substrate 26 will form the drain layer 26 of the completed JFET device.

An n-epitaxial layer 15 having a thickness of about 8 microns is formed on the substrate 26. Such an epitaxial layer thickness is appropriate for a device having a blocking voltage of 600-800 V. For higher voltage ratings, the n-epitaxial layer 15 would be thicker. The n- epitaxial layer 15 may have a doping concentration of between about 5E15 cm⁻³ and 1E17 cm⁻³, and in some embodiments between about 1E16 cm⁻³ and 5E16 cm⁻³. In particular embodiments, the n- epitaxial layer 15 may have a doping concentration of about 1.5E16 cm⁻³. The thickness and/or doping of the n- epitaxial layer 15, which forms the drift layer of the device, may be selected to provide a desired on-state resistance and/or off-state voltage blocking capability for the device.

Referring to FIG. 4B, an n+ source layer 16 and an n++ source contact layer are formed by implanting n-type ions, such as silicon, into the epitaxial layer 15 at doses and implant energies. The n+ source layer 16 may have a thickness of about 0.5 microns and a doping concentration of about 1E18 cm⁻³. The n+ source contact layer 38 may have a thickness of about 0.5 microns and may be degenerately doped to allow formation of a source ohmic contact thereto.

Referring to FIG. 4C, a mask 46 is formed on an upper surface of the structure. The mask 46 is formed to have a thickness of about 1 micron and is formed by depositing a layer 46A of SiO₂ by plasma enhanced chemical vapor deposition (PECVD) followed by a layer 46B of silicon nitride. The structure is then etched to form a trench 48 that defines a mesa 12. As in FIGS. 2A-2B, only half of the structure to the right of the axis 30 is shown for ease of understanding. The trench 48 has a width of about 1.2 microns, and the mesa has a total width of about 1.2 microns. The trench 48 may be etched to about 2 microns deep in the n- epitaxial layer 15.

Following the trenching operation, the mask 46 may have a remaining thickness of about 0.7 microns. Referring to FIG. 4D, with the mask 46 in place, a tilted ion implantation 50 is performed to implant the n+ shallow channel region 124 into the sidewall of the mesa 12. The n+ shallow channel region 124 is implanted with a dose sufficient to obtain a doping concentration of about 1E17 cm⁻³ to 1E19 cm⁻³, and in some cases about 3E17 cm⁻³ to 5E18 cm⁻³. The n+ shallow channel region 124 may be implanted at a maximum implant energy of about 700 to 800 keV to obtain a desired implant depth. The implants may be performed multiple times at high temperature and a tilt angle of 35 to 40 degrees from normal to ensure that the bottom of the trench sidewall is not screened. The implants may be performed at four twist angles that are spaced 90 degrees apart from each other.

Referring to FIG. 4E, a second SiO₂ layer 48 is deposited onto the structure and patterned to form openings 49 in an edge termination region 57 of the structure. The conditions of the pattern etch are chosen to use the underlying silicon nitride layer 46B as an etch stop so that the mask 46 is not removed when the second SiO₂ layer 48 is patterned. A tilted ion implantation 52 is performed to implant the p+ gate region 18 into the sidewall of the mesa 12 and to simultaneously implant edge termination regions 55 into the edge termination region 57. The p+ gate 18 is implanted with a dose sufficient to obtain a doping concentration of about 1E18 cm⁻³ to 1E19 cm⁻³. The p+ gate region 18 may be implanted at a maximum implant energy of about 300-400 keV to obtain a desired implant depth. The implants may be performed multiple times at high temperature and a tilt angle of 35 to 40 degrees from normal to ensure that the bottom of the trench sidewall is not screened. The implants may be performed at four twist angles that are spaced 90 degrees apart from each other.

Referring to FIG. 4F, an ion implantation operation 54 is performed to implant a p++ shield region 32 in the surface of the trench 48. In the ion implantation operation 54, p-type ions may be implanted into the surface of the trench at a maximum implant energy of about 350 keV. Following the ion implantation operation 54, a junction termination extension (JTE) region (not shown) may be formed in the edge termination region 57 by ion implantation. All of the implanted dopants may then be activated by annealing at 1550 C for 30 minutes using a carbon cap.

Referring to FIG. 4G, a layer of SiO₂ may then be deposited over the structure using PECVD and isotropically etched, for example using an inductively coupled plasma (ICP) etch, to form a sidewall protection layer 61 on the exposed sidewall of the mesa 12 adjacent the trench 48. The sidewall protection layer 61 may have a thickness of, for example, 20 to 30 nm, in some embodiments 23 to 27 nm and in some embodiments 25 nm.

Referring to FIG. 4H, a layer 63 of Ni having a thickness of 100 nm may be deposited on the structure and annealed at 750° C. to form a silicide at the bottom of the trench 48. Unreacted Ni may then be etched, and the structure annealed at 1000° C. or lower to form a gate ohmic contact 36 on the p+ shield region 32 in a gate pad region and a source ohmic contact 40 on the source contact layer 38. Additional conventional fabrication processes, such as trench fill 72, planarization, metallization 74, backside metallization 76 and laser annealing may then be performed to complete the device fabrication as shown in FIG. 4I.

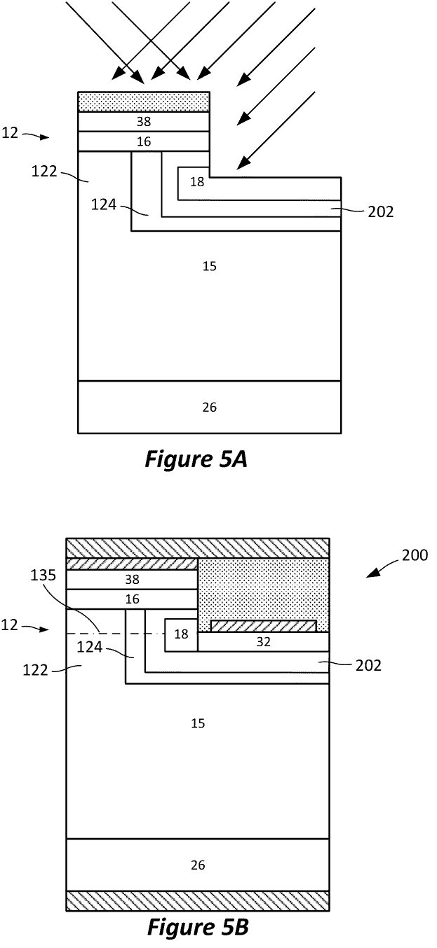

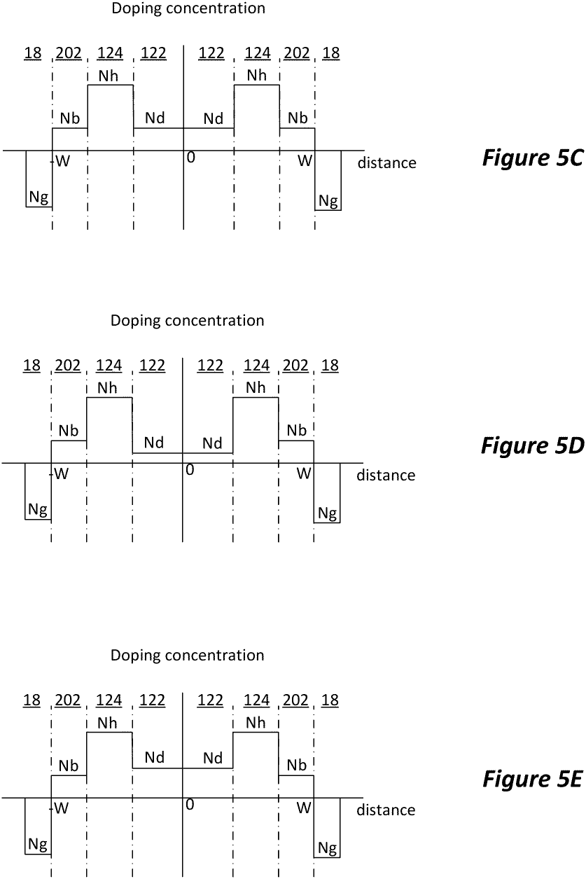

FIG. 5A illustrates operations for fabricating a JFET device structure according to further embodiments. As shown in FIG. 5A, in some embodiments, the implant energies and doses of the n-type implant 50 (FIG. 4D) to form the shallow conduction region 124 and the p-type implant 52 (FIG. 4E) to form the gate region 18 may be selected so that after implantation and annealing, an n-breakdown adjustment region 202 remains around the gate region 18, including between the shallow conduction region 124 and the gate region 18 and between the source region 16 and the gate region 18. The shallow conduction region 124 is between the deep conduction region 122 and the breakdown adjustment region 202. The breakdown adjustment region 202 may have a net n-type doping concentration of about 5E15 cm⁻³ to about 1E17 cm⁻³, in some embodiments about 1E16 cm⁻³ to about 5E16 cm⁻³, and in particular embodiments about 1.5E16 cm⁻³. The breakdown adjustment region 202 may have a doping concentration that is similar to that of the deep conduction region 122, but does not have to be equal to the doping concentration of the deep conduction region 122.

The breakdown adjustment region 202 is provided so that the gate-source P-N junction is formed by the p+ gate region 18 and an n- region. This may increase the gate-source breakdown voltage. The n- breakdown adjustment region 202 surrounding the p+ gate region 18 is also self-aligned to the edge of the mesa 12, and could be formed in some embodiments using tilted implants by adding a lower-energy n-implant.

FIG. 5B illustrates a JFET device structure 200 including an n- breakdown adjustment region 202 between the shallow conduction region 124 and the gate region 18, and FIGS. 5C, 5D and 5E illustrate some possible channel doping profiles for the JFET device structure of FIG. 5B. As seen in FIG. 5C, the breakdown adjustment region 202 has a doping concentration N_{b} which is less than the doping concentration Nₕ of the shallow conduction region 124.

The doping concentration N_{b} may be greater than, less than or equal to the doping concentration N_{d} of the deep conduction region 122. For example, in FIG. 5C, the breakdown adjustment region 202 has a doping concentration N_{b} which is about equal to the doping concentration N_{d} of the deep conduction region 122. FIG. 5D illustrates a doping profile in which the doping concentration N_{b} of the breakdown adjustment region 202 is higher than the doping concentration N_{d} of the deep conduction region 122, and FIG. 5E illustrates a doping profile in which the doping concentration N_{b} of the breakdown adjustment region 202 is less than the doping concentration N_{d} of the deep conduction region 122.

Although illustrated as an n-channel device, it will be appreciated that the JFET device structure 200 could be formed as a p-channel device by switching the n-type layers to p-type, and vice versa.

A SiC JFET device according to some embodiments may provide improved yields due to reduced sensitivity of threshold voltage to mesa width. Alternatively or additionally, such a device can maintain yields while allowing a tighter design (e.g., a narrower mesa) that improves performance.

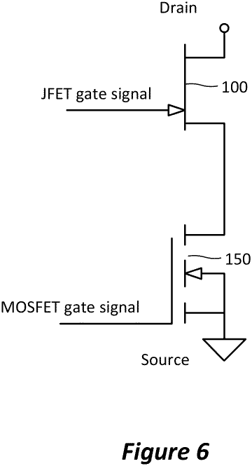

FIG. 6 illustrates an example circuit that includes a JFET device according to some embodiments. As shown in FIG. 6, a vertical SiC JFET 100 according to some embodiments can be connected in a modified cascode topology with a Silicon MOSFET 150, where the SiC JFET gate is direct-driven, and in which it is desirable for the variation of SiC JFET threshold voltage to be very low.

A JFET device as described herein may also be advantageously used for other SiC JFET applications such as in a solid-state circuit breaker as a normally-on SiC JFET switch.

More broadly, some embodiments described herein can be used in any vertical channel junction field effect device with a mesa/trench feature where an important property of the device is sensitive to mesa width and it is of interest to reduce the sensitivity of that property to mesa width.

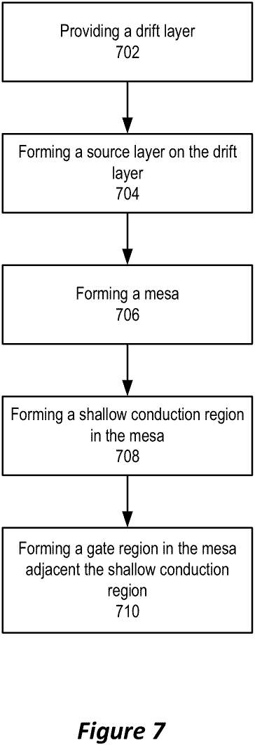

FIG. 7 illustrates a method of forming a vertical junction field effect transistor. The method includes providing a drift layer having a first conductivity type (block 702), forming a source layer having the first conductivity type on the drift layer (block 704), and forming a mesa by selectively etching a portion of the source layer and the drift layer to form a trench that extends into the drift layer and defines the mesa adjacent the trench (block 706). The has a mesa sidewall adjacent the trench. The method further includes forming a shallow conduction region in the mesa that extends between the drift layer and the source layer (block 708), and forming a gate region having a second conductivity type in the mesa (block 710). The gate region is adjacent a channel region in the mesa, and the channel region includes a deep conduction region adjacent the shallow conduction region such that the shallow conduction region is between the deep conduction region and the gate region. The shallow conduction region has a higher doping concentration than the deep conduction region.

Forming the shallow conduction region may include performing an angled ion implantation of first conductivity type dopant ions into the mesa sidewall at a first implant energy to form the shallow conduction region in the mesa, wherein a portion of the drift layer in the mesa forms the deep conduction region adjacent the shallow conduction region.

Forming the gate region may include implanting second conductivity type dopant ions into the mesa sidewall at a second implant energy that is lower than the first implant energy to form the gate region in the mesa, wherein the shallow conduction region is between the gate region and the deep conduction region, and wherein the second conductivity type is opposite the first conductivity type.

In some embodiments, forming the mesa includes forming an etch mask on the source layer, and etching the source layer and the drift layer to form the mesa in a region below the etch mask. Forming the shallow conduction region may include implanting the first conductivity type dopant ions into the mesa sidewall using the etch mask as an implant mask.

The etch mask may include an SiO₂ etch mask on the source layer and a silicon nitride mask on the SiO₂ mask, and the method may further include forming a second etch mask on the mesa and the trench, patterning the second etch mask to expose the mesa and a floor of the trench adjacent the mesa, and to expose one or more surface regions in an edge region of the device, and implanting second conductivity type dopant ions into the mesa sidewall and the junction termination regions at a second implant energy that is lower than the first implant energy to form the gate region in the mesa and to form edge termination regions in the edge region. The shallow conduction region is between the gate region and the deep conduction region, and the second conductivity type is opposite the first conductivity type.

The second etch mask may include SiO₂, and patterning the second etch mask includes selectively etching the second etch mask using the silicon nitride mask as an etch stop layer.

Although embodiments of the inventive concepts have been described in considerable detail with reference to certain configurations thereof, other versions are possible. The field plates and gates can also have many different shapes and can be connected to the source contact in many different ways. Accordingly, the spirit and scope of the invention should not be limited to the specific embodiments described above.

1. A power transistor device, comprising:
a drift layer (15) having a first conductivity type;
a mesa (12) on the drift layer, the mesa comprising a channel region (114) on the drift layer and a source layer (16) on the channel region, the channel region and the source layer having the first conductivity type; and
a gate region (18) in the mesa adjacent the channel region, the gate region having a second conductivity type opposite the first conductivity type;
wherein the channel region comprises a deep conduction region (122) and a shallow conduction region (124) between the deep conduction region and the gate region;
wherein the deep conduction region has a first doping concentration, and the shallow conduction region has a second doping concentration that is greater than the first doping concentration.

2. The power transistor device of claim 1, wherein the shallow conduction region extends vertically between the drift layer and the source layer, and wherein the deep conduction region extends vertically between the drift layer and the source layer.

3. The power transistor device of claim 1, wherein the channel region comprises silicon carbide, and wherein the shallow conduction region has a doping concentration greater than about 1E17 cm⁻³ and the deep conduction region has a doping concentration less than about 1E17 cm⁻³.

4. The power transistor device of claim 1, wherein the channel region comprises silicon carbide, and wherein the shallow conduction region has a doping concentration of between about 3E17 cm⁻³ and about 5E18 cm⁻³, and the deep conduction region has a doping concentration of about 1E16 cm⁻³ to about 5E16 cm⁻³.

5. The power transistor device of claim 4, wherein the shallow conduction region has a doping concentration of about 1E18 cm⁻³ and the deep conduction region has a doping concentration of about 1.5E16 cm⁻³.

6. The power transistor device of claim 1, wherein the shallow conduction region has a doping concentration at least about 10 times greater than a doping concentration of the deep conduction region.

7. The power transistor device of claim 1, wherein the shallow conduction region has a graded doping profile that is graded in a lateral direction that is perpendicular to a direction of carrier flow through the channel region when the vertical junction field effect device is in an on-state.

8. The power transistor device of claim 1, wherein the shallow conduction region has a breadth of about 0.1 to 0.3 microns in a lateral direction that is perpendicular to a direction of carrier flow through the channel region when the vertical junction field effect device is in an on-state.

9. The power transistor device of claim 1, wherein the shallow conduction region has a breadth in a lateral direction that is perpendicular to a direction of carrier flow through the channel region when the vertical junction field effect device is in an on-state that is about one third of a half-width of the mesa.

10. The power transistor device of claim 1, wherein the shallow conduction region comprises an implanted region within the mesa.

11. The power transistor device of claim 1, further comprising:
a breakdown adjustment region between the shallow conduction region and the gate region, wherein the breakdown adjustment region has the first conductivity type and has a third doping concentration less than the second doping concentration of the shallow conduction region.

12. The power transistor device of claim 1, wherein the channel region comprises silicon carbide, and wherein the vertical junction field effect device exhibits a change in threshold voltage as a function of mesa width of less than 20 V/micron.

13. The power transistor device of claim 1, wherein the channel region comprises silicon carbide, and wherein the vertical junction field effect device exhibits a change in threshold voltage as a function of mesa width of less than 10 V/micron.

14. The power transistor device of claim 1, wherein the channel region comprises silicon carbide, and wherein the vertical junction field effect device exhibits a change in threshold voltage as a function of mesa width of less than 5 V/micron.

15. The power transistor device of claim 1, wherein the channel region comprises silicon carbide, and wherein the vertical junction field effect device exhibits a change in threshold voltage as a function of mesa width between 5 V/micron and 20 V/micron.

16. The power transistor device of claim 1, wherein the power transistor device comprises a junction field effect transistor (JFET).

17. The power transistor device of claim 1, wherein the drift layer, the channel region and the gate region comprise silicon carbide.

18. The power transistor device of claim 1, wherein a breadth of the shallow channel region in a lateral direction that is perpendicular to a direction of current flow when the device is in an on-state is independent of a width of the mesa in the lateral direction.

19. The power transistor device of claim 1, wherein a breadth of the deep channel region in a lateral direction that is perpendicular to a direction of current flow when the device is in an on-state is directly proportional to a width of the mesa in the lateral direction.

20. The power transistor device of claim 1, wherein the gate region comprises a first gate region and the shallow conduction region comprises a first shallow conduction region, the power transistor device further comprising:
a second gate region in the mesa opposite the first gate region, wherein the channel region is between the first gate region and the second gate region; and
a second shallow conduction region in the channel region between the deep conduction region and the second gate region;
wherein the second shallow conduction region has a third doping concentration that is greater than the first doping concentration of the deep conduction region.

21. The power transistor device of claim 20, wherein the first gate region is surrounded by a breakdown adjustment region in the mesa, the breakdown adjustment region having the first conductivity type and having a third doping concentration that is less than the second doping concentration of the shallow conducting region.

22. The power transistor device of claim 1, wherein the deep conduction region and the channel region are arranged on opposite sides of the shallow conduction region in a lateral direction that is perpendicular to a direction of current flow in the power transistor device.

23. A power transistor device, comprising:
a drift layer (10) having a first conductivity type;
a mesa (12) on the drift layer, the mesa comprising a channel region (14) on the drift layer and a source layer (16) on the channel region, the channel region and the source layer having the first conductivity type; and
a gate region (18) in the mesa on a side of the channel region, the gate region having a second conductivity type opposite the first conductivity type;
wherein the vertical junction field effect device exhibits a change in threshold voltage as a function of mesa width of less than 20 V/micron.

24. The power transistor device of claim 23, wherein the channel region comprises silicon carbide, and wherein the vertical junction field effect device exhibits a change in threshold voltage as a function of mesa width of less than 10 V/micron.

25. The power transistor device of claim 23, wherein the channel region comprises silicon carbide, and wherein the vertical junction field effect device exhibits a change in threshold voltage as a function of mesa width of less than 5 V/micron.

26. The power transistor device of claim 23, wherein the channel region comprises silicon carbide, and wherein the vertical junction field effect device exhibits a change in threshold voltage as a function of mesa width between 5 V/micron and 20 V/micron.

27. The power transistor device of claim 23, wherein the channel region comprises a deep conduction region (122) and a shallow conduction region (124) between the deep conduction region and the gate region;
wherein the deep conduction region has a first doping concentration, and the shallow conduction region has a second doping concentration that is greater than the first doping concentration.

28. The power transistor device of claim 27, wherein the shallow conduction region extends vertically between the drift layer and the source layer, and wherein the deep conduction region extends vertically between the drift layer and the source layer.

29. The power transistor device of claim 27, wherein the channel region comprises silicon carbide, and wherein the shallow conduction region has a doping concentration greater than about 1E17 cm⁻³ and the deep conduction region has a doping concentration less than about 1E17 cm⁻³.

30. The power transistor device of claim 27, wherein the shallow conduction region has a graded doping profile that is graded in a lateral direction that is perpendicular to a direction of carrier flow through the channel region when the vertical junction field effect device is in an on-state.

31. The power transistor device of claim 27, wherein the shallow conduction region has a breadth in a lateral direction that is perpendicular to a direction of carrier flow through the channel region when the vertical junction field effect device is in an on-state that is about one third of a half-width of the mesa.

32. The power transistor device of claim 27, further comprising:
a breakdown adjustment region between the shallow conduction region and the gate region, wherein the breakdown adjustment region has the first conductivity type and has a third doping concentration less than the second doping concentration of the shallow conduction region.

33. A method of forming a power transistor device, comprising:
providing (702) a drift layer having a first conductivity type;
forming (704) a source layer having the first conductivity type on the drift layer;
forming (706) a mesa by selectively etching a portion of the source layer and the drift layer to form a trench that extends into the drift layer and defines the mesa adjacent the trench, the mesa having a mesa sidewall adjacent the trench;
forming (708) a shallow conduction region in the mesa that extends between the drift layer and the source layer; and
forming (710) a gate region having a second conductivity type in the mesa, wherein the gate region is adjacent a channel region in the mesa, wherein the channel region includes a deep conduction region adjacent the shallow conduction region and the shallow conduction region is between the deep conduction region and the gate region;
wherein the shallow conduction region has a higher doping concentration than the deep conduction region.

34. The method of claim 33, wherein forming the shallow conduction region comprises performing an angled ion implantation of first conductivity type dopant ions into the mesa sidewall at a first implant energy to form the shallow conduction region in the mesa, wherein a portion of the drift layer in the mesa forms the deep conduction region adjacent the shallow conduction region.

35. The method of claim 34, wherein forming the gate region comprises implanting second conductivity type dopant ions into the mesa sidewall at a second implant energy that is lower than the first implant energy to form the gate region in the mesa, wherein the shallow conduction region is between the gate region and the deep conduction region, and wherein the second conductivity type is opposite the first conductivity type.

36. The method of claim 34, wherein forming the mesa comprises:
forming an etch mask on the source layer; and
etching the source layer and the drift layer to form the mesa in a region below the etch mask, wherein forming the shallow conduction region comprises implanting the first conductivity type dopant ions into the mesa sidewall using the etch mask as an implant mask.

37. The method of claim 36, wherein the etch mask comprises an SiO₂ etch mask on the source layer and a silicon nitride mask on the SiO₂ mask, the method further comprising:
forming a second etch mask on the mesa and the trench;
patterning the second etch mask to expose the mesa and a floor of the trench adjacent the mesa, and to expose one or more surface regions in an edge region of the device; and
implanting second conductivity type dopant ions into the mesa sidewall and the junction termination regions at a second implant energy that is lower than the first implant energy to form the gate region in the mesa and to form edge termination regions in the edge region, wherein the shallow conduction region is between the gate region and the deep conduction region, and wherein the second conductivity type is opposite the first conductivity type.

38. The method of claim 37, wherein the second etch mask comprises SiO₂, and wherein patterning the second etch mask comprises selectively etching the second etch mask using the silicon nitride mask as an etch stop layer.

39. A power transistor device, comprising:
a drift layer (10) having a first conductivity type;
a mesa (12) on the drift layer, the mesa comprising a channel region (114) on the drift layer and a source layer (16) on the channel region, the channel region and the source layer having the first conductivity type; and
a gate region (18) in the mesa adjacent the channel region, the gate region having a second conductivity type opposite the first conductivity type;
a breakdown adjustment region (202) in the mesa between the channel region and the gate region, the breakdown adjustment region having the first conductivity type;
wherein the channel region has a first doping concentration and wherein the breakdown adjustment region has a second doping concentration that is less than the first doping concentration.

40. The power transistor device of claim 39, wherein the channel region comprises a deep conduction region (122) and a shallow conduction region (124) between the deep conduction region and the breakdown adjustment region;
wherein the shallow conduction region has the first doping concentration and the deep conduction region has a third doping concentration that is less than the first doping concentration.

41. The power transistor device of claim 39, wherein the breakdown adjustment region is above and below the gate region in the mesa, and on a side of the gate region adjacent the channel region in the mesa.
